(19) United States
(12) Patent Application Publication
(10) Pub. No.: US 2013/0214338 A1
(43) Pub. Date: Aug. 22, 2013

(54) SEMICONDUCTOR DEVICE

(71) Applicant: Elpida Memory, Inc., (US)

(72) Inventor: Noriaki MIKASA, Tokyo (JP)

(73) Assignee: Elpida Memory, Inc., Tokyo (JP)

(21) Appl. No.: 13/733,596

(22) Filed: Jan. 3, 2013

(30) Foreign Application Priority Data
Jan. 10, 2012 (JP) 2012-002015

(51) Int. Cl. H01L 29/78; H01L 27/06

(52) U.S. Cl. CPC H01L 29/7827; H01L 27/0629
USPC 257/296; 257/330

(57) ABSTRACT

A semiconductor device comprises a convex portion, a concave portion provided so as to cover upper and side surfaces of the convex portion, a gate electrode provided so as to be opposed to the convex portion with a gate insulating film interposed between the gate electrode and the convex portion, a pair of diffusion layers provided within the convex portion so as to sandwich the gate electrode, and a contact plug provided on the concave portion, so as to be electrically connected to at least one of the diffusion layers.

This application is based upon and claims the benefit of priority from Japanese Patent Application No. 2012-002015 filed on Jan. 10, 2012, the disclosure of which are incorporated herein in its entirety by reference.

### BACKGROUND OF THE INVENTION

1. Field of the Invention

The present invention relates to a semiconductor device.

2. Description of the Related Art

A DRAM (Dynamic Random Access Memory) is available as a semiconductor memory typical of large-capacity memories. The memory capacity of this DRAM tends to increase in recent years. Consequently, there has arisen the need to enhance the degree of integration of memory cells of the DRAM.

Miniaturizing memory cell transistors is the most effective means for realizing the high integration of the DRAM. By reducing a feature size (F), each memory cell transistor can be miniaturized to enhance the degree of integration. It is also important to reduce a cell size by changing a cell method, in addition to this reduction in the feature size. As a cell method effective for a reduction in the cell size, there has been proposed a method in which cells are arranged into a meander shape. As illustrated in FIG. 16, this cell method includes a plurality of active regions AR1 and AR2, which are surrounded by isolation region 30. Active region AR1 extends in direction X₂ inclined approximately 30° diagonally right down from an X direction and are arranged at equal pitches in a Y direction. Active region AR2 extends in direction X₁ inclined approximately 30° diagonally right up from the X direction and are arranged at equal pitches in the Y direction. Thus, active regions AR1 and AR2 are arranged alternately at equal pitches in the X direction. Cell transistors, capacitor contact plugs, and capacitors (none of which are illustrated) are formed within respective active regions AR1 and AR2 and on and above these active regions, thereby constituting memory cells.

In the cell method in which meander-shaped cells are arranged, however, lithography steps using an ArF laser and dry etching steps have to be carried out more than once at the time of forming active regions, thus resulting in a complicated process. Accordingly, forming meander-shaped active regions with high accuracy has become increasingly difficult along with progress in the miniaturization of DRAMs.

Hence, a cell method in which straight-line active regions are arranged such that a plurality of active regions extends in the same direction is expected as the effective cell method from the viewpoint of miniaturization. In this cell method, the respective active regions extend in the same direction and are relatively simple in shape, as compared with the meander active regions. Thus, the cell method can be expected to allow the formation of active regions with a simple process.

JP2011-159760A and JP2009-212369A disclose straight-line active regions.

### SUMMARY OF THE INVENTION

In one embodiment, there is provided a semiconductor device comprising:
a convex portion;
a concave portion provided so as to cover an upper surface and a part of a side surface of the convex portion;
a gate electrode provided within the convex portion, so as to be opposed to the convex portion with a gate insulating film interposed between the gate electrode and the convex portion;
a pair of diffusion layers provided so as to sandwich the gate electrode within the convex portion and the concave portion; and
a contact plug provided on the concave portion, so as to be electrically connected to at least one of the diffusion layers.

In another embodiment, there is provided a semiconductor device comprising:
a first region including an upper portion, a lower portion having a smaller width than the upper portion, and a level difference formed by a discontinuous variation of widths of the upper portion and the lower portion;
a gate electrode provided within the first region, so as to be opposed to the first region with a gate insulating film interposed between the gate electrode and the first region;
a pair of diffusion layers provided within the first region so as to sandwich the gate electrode; and
a contact plug provided on the upper portion, so as to abut on at least one of the diffusion layers.

In another embodiment, there is provided a semiconductor device comprising:
a first region including a first upper portion and a first lower portion having a smaller width than the first upper portion;
a second region including a second upper portion and a second lower portion having a smaller width than the second upper portion;
a first isolation region provided between the first and second regions, so as to cover side surfaces of the first and second regions;
a first gate electrode provided within the first region, so as to be opposed to the first region with a first gate insulating film interposed between the first gate electrode and the first region;
a second gate electrode provided within the second region, so as to be opposed to the second region with a second gate insulating film interposed between the second gate electrode and the second region;
a pair of first diffusion layers provided within the first region so as to sandwich the first gate electrode;
a pair of second diffusion layers provided within the second region so as to sandwich the second gate electrode;
a first contact plug provided on the first region, so as to be electrically connected to at least one of the first diffusion layers; and
a second contact plug provided on the second region, so as to be electrically connected to at least one of the second diffusion layers.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic view used to describe one step of a method for manufacturing a semiconductor device according to a first exemplary embodiment;

FIG. 2 is another schematic view used to describe one step of the method for manufacturing a semiconductor device according to the first exemplary embodiment;

FIG. 3 is yet another schematic view used to describe one step of the method for manufacturing a semiconductor device according to the first exemplary embodiment;

FIG. 4 is still another schematic view used to describe one step of the method for manufacturing a semiconductor device according to the first exemplary embodiment;

FIG. 5 is still another schematic view used to describe one step of the method for manufacturing a semiconductor device according to the first exemplary embodiment;

FIG. 6 is still another schematic view used to describe one step of the method for manufacturing a semiconductor device according to the first exemplary embodiment;

FIG. 7 is still another schematic view used to describe one step of the method for manufacturing a semiconductor device according to the first exemplary embodiment;

FIG. 8 is still another schematic view used to describe one step of the method for manufacturing a semiconductor device according to the first exemplary embodiment;

FIG. 9 is still another schematic view used to describe one step of the method for manufacturing a semiconductor device according to the first exemplary embodiment;

FIG. 10 is still another schematic view used to describe one step of the method for manufacturing a semiconductor device according to the first exemplary embodiment;

FIG. 11 is still another schematic view used to describe one step of the method for manufacturing a semiconductor device according to the first exemplary embodiment;

FIG. 12 is still another schematic view used to describe one step of the method for manufacturing a semiconductor device according to the first exemplary embodiment;

FIG. 13 is still another schematic view used to describe one step of the method for manufacturing a semiconductor device according to the first exemplary embodiment;

FIG. 14 is still another schematic view used to describe one step of the method for manufacturing a semiconductor device according to the first exemplary embodiment;

FIG. 15 is a schematic view used to describe a semiconductor device of a second exemplary embodiment; and

FIG. 16 is a schematic view used to describe a cell method including meander-shaped active regions.

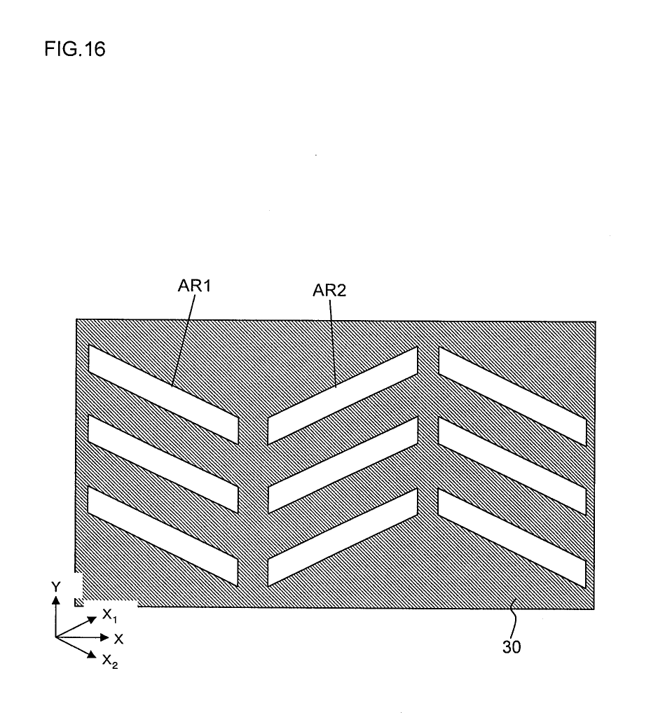

In the drawings, numerals have the following meanings, 1: active region, 1a: convex portion (lower portion), 1b: concave portion (upper portion), 1c: level difference, 1d, 1e, 1f: surface, 3: first isolation region, 3a: silicon nitride film (first insulating film), 3b: silicon oxynitride film (second insulating film), 3c: upper surface of silicon oxynitride film, 4: gate insulating film, 5: buried gate electrode, 6: cap insulating layer, 7: first interlayer insulating film, 8: sidewall insulating film, 9: capacitor contact plug, 10: cover insulating film, 11: bit line, 11a: opening, 11b: bit-line contact plug, 12: contact pad, 13: second interlayer insulating film, 14: lower electrode, 15: capacitive insulating film, 16: upper electrode, 17: support film, 20: semiconductor substrate, 20a: upper surface of substrate, 22a: bit-line diffusion layer, 22b: capacitor diffusion layer, 23: gate trench, 23a, 23c, 23d, 23f: side surface of gate trench, 23b, 23e: bottom surface of gate trench, 23g, 23h: bottom diffusion layer, 24: capacitive contact hole, 25: pad oxide film, 26a: first trench, 26b: second trench, 27: SOD film, 28: polysilicon film, 29: DOPOS film, 30: second isolation region, 31: gate trench, 32: capacitor hole, 50: mask pattern, AR1, AR2: active region, Cap: capacitor, T₁: thickness of silicon nitride film, Tr1, Tr2: cell transistor, X₁: width of convex portion (lower portion), and X₂: width of concave portion (upper portion).

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

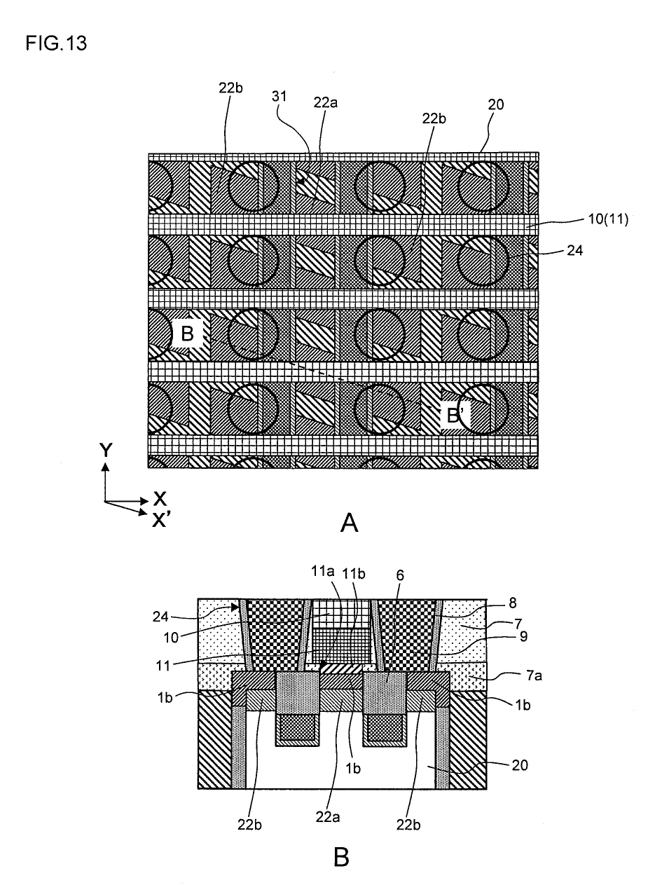

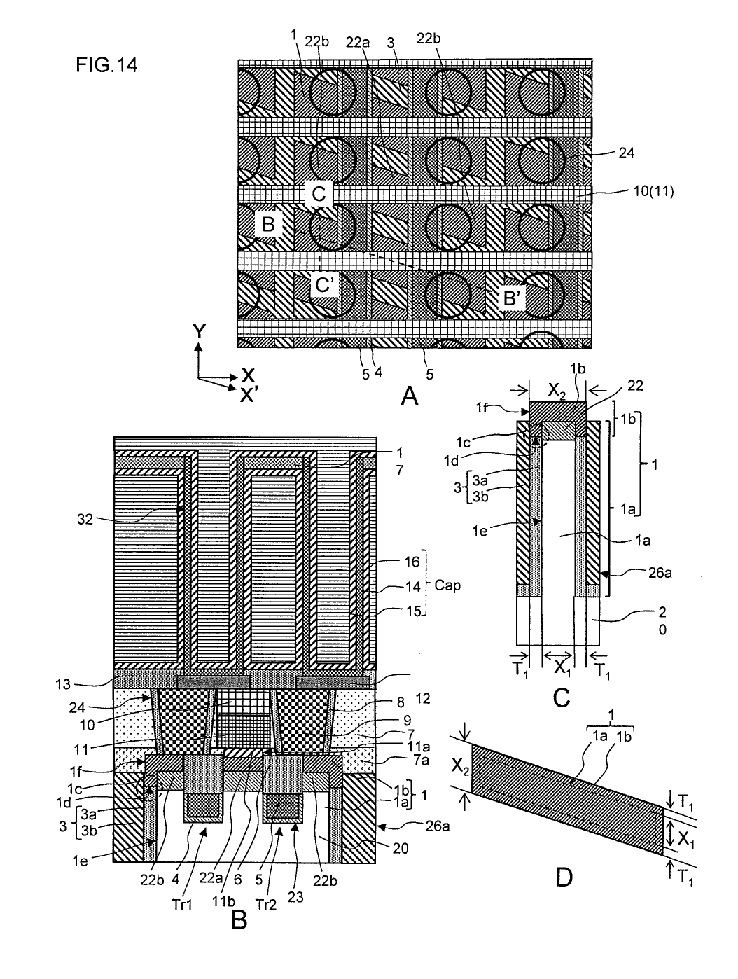

FIG. 14 is a group of schematic views representing a semiconductor device of the present exemplary embodiment. FIG. 14A is a plan view of part of a memory cell region of the semiconductor device, FIGS. 14B and 14C are schematic views respectively representing the B-B′ cross section and the C-C′ cross section of FIG. 14A, and FIG. 14D is a schematic view taken from above one active region 1 whose portion surrounded by a dotted line perspectively represents convex portion (lower portion) 1a of the active region. Note that in FIG. 14A, some of structures, including capacitor Cap and interlayer insulating film 7, are omitted, in order to clarify the positional relationship among active region 1, bit line 11 and gate electrode 5. This is also true for FIG. 13A to be discussed later. In addition, in FIG. 14C, only active region 1 and first isolation region 3 are shown and the other structures are omitted. In the description given hereinafter, widths X₁ and X₂ of active region 1 refer to widths of active region 1 in the short-side direction thereof in plan view (extending direction of gate electrode 5). This direction is not perpendicular to extending direction X′ of active region 1.

As illustrated in FIG. 14, the semiconductor device of the present exemplary embodiment includes a plurality of active regions 1 extending in the X′ direction on monocrystalline silicon semiconductor substrate 20 and arranged at equal pitches in the Y direction. Each active region 1 includes convex portion (lower portion) 1a composed of part of silicon semiconductor substrate 20, and concave portion (upper portion) 1b provided so as to continuously cover the upper and side surfaces of convex portion 1a. As illustrated in FIG. 14C, concave portion (upper portion) 1b has an upside-down concave shape, and is structured such that the leading end of convex portion (lower portion) 1a abuts on the recess of the concave shape. Concave portion (upper portion) 1b is composed of, for example, a monocrystalline silicon film (conductive film) containing an n-type impurity. As will be discussed in a later-described manufacturing method, concave portion 1b is converted into a monocrystalline silicon film by a solid-phase epitaxial growth method using a monocrystal surface of semiconductor substrate 20 produced by heat-treating an amorphous silicon film formed on monocrystal semiconductor substrate 20 as a seed. Concave portion 1b is not limited to the monocrystalline silicon film but may be composed of a polysilicon film. In addition, impurity-diffused layer 22 is provided on a top portion of convex portion 1a. As illustrated in FIGS. 14B to 14D, width X₂ of concave portion (upper portion) 1b is larger than width X₁ of convex portion (lower portion) 1a. Thus, concave portion 1b is provided so as to laterally protrude from side surfaces 1e of convex portion 1a. Yet additionally, the width of each active region 1 discontinuously varies from width X₂ of concave portion 1b to width X₁ of convex portion 1a. Consequently, level difference 1c formed of lower surface 1d of concave portion 1b is present between outer side surface 1f of concave portion 1b and side surface 1e of convex portion 1a.

First isolation region 3 is provided around each active region 1 and, thus, each active region 1 is defined by first isolation region 3. First isolation region 3 is composed of silicon nitride film (first insulating film) 3a provided so as to cover the inner surfaces of first trench 26a for the first isolation region, and silicon oxynitride film (second insulating film) 3b buried in a concave portion inside trench 26a made of silicon nitride film 3a. The upper surface of silicon nitride film 3a abuts on the lower surface of concave portion 1b protruding laterally from side surfaces 1e of convex portion 1a (the upper surface of silicon nitride film 3a and the lower surface of concave portion 1b are collectively shown as surface 1d in FIGS. 14B and 14C). One side surface of silicon nitride film 3a abuts on side surface 1e of convex portion 1a (the side surfaces of silicon nitride film 3a and convex portion 1a are collectively shown as surface 1e in FIGS. 14B and 14C). Accordingly, as for the relationship among width X₂ of concave portion (upper portion) 1b, width X₁ of convex portion (lower portion) 1a, and film thickness T₁ of silicon nitride film 3a mentioned above, X₂=X₁+2×T₁. In addition, silicon oxynitride film 3b is provided on silicon nitride film 3a, so as to fill trench 26a, and abuts on the other side surface of silicon nitride film 3a and on part of outer side surface 1f of concave portion 1b. The other side surface of silicon nitride film 3a and outer side surface 1f of concave portion 1b are flush with each other.

Referring to the plan view of FIG. 14A, there are arranged a plurality of bit lines 11 extending in the X direction and a plurality of buried gate electrodes 5 to serve as word lines intersecting perpendicularly with the X direction and extending in the Y direction. Two buried gate electrodes 5 extending in the Y direction are buried in convex portion 1a and concave portion 1b of each active region 1 and, thus, arranged therein across active region 1. Bit-line diffusion layer 22a to be connected to bit line 11 is formed in a portion of active region 1 positioned between two buried gate electrodes 5. In addition, capacitor diffusion layer 22b to be connected to lower electrode 14 of capacitor Cap are respectively formed in portions of active region 1 positioned at both ends of active region 1 and between each buried gate electrode 5 and first isolation region 3. Each buried gate electrode 5 extending in the Y direction is formed across a plurality of active regions 1 arranged in the Y direction and first isolation regions 3 arranged among the plurality of active regions 1. In addition, each of the plurality of bit lines 11 extending in the X direction is formed on a straight line connecting bit-line diffusion layers 22a of a plurality of active regions 1 arranged in the X direction. In the present exemplary embodiment, bit-line diffusion layers 22a and capacitor diffusion layers 22b are composed of an n-type impurity-containing diffusion layer.

As illustrated in FIG. 14B, two cell transistors Tr1 and Tr2 are formed in each active region 1. Both of the transistors are composed of a buried gate-type recess-channel MOS transistor. Cell transistor Tr1 is composed of a portion of silicon substrate 20, buried gate electrode 5, concave portions 1b and capacitor diffusion layers 22b positioned on both sides of buried gate electrode 5 with the buried gate electrode therebetween, middle concave portion 1b and bit-line diffusion layer 22a, and gate insulating film 4. As a matter of convenience, concave portion 1b and capacitor diffusion layer 22b thereunder serve as a drain region, and concave portion 1b and bit-line diffusion layer 22a thereunder serve as a source region. These respective regions alternate with each other each time a state of biasing is reversed. Like cell transistor Tr1, cell transistor Tr2 is composed of a portion of silicon substrate 20, buried gate electrode 5, concave portions 1b and bit-line diffusion layers 22a positioned on both sides of buried gate electrode 5 with the buried gate electrode 5 therebetween, concave portion 1b and capacitor diffusion layer 22b, and gate insulating film 4. As a matter of convenience, concave portion 1b and bit-line diffusion layer 22a thereunder serve as a source region, and concave portion 1b and capacitor diffusion layer 22b thereunder serve as a drain region. The source region composed of concave portion 1b and bit-line diffusion layer 22a is shared by two cell transistors Tr1 and Tr2. The channel regions of each of cell transistors Tr1 and Tr2 are formed in both sidewalls and the bottom surface (a surface of silicon semiconductor substrate 20 abutting on gate insulating film 4) of gate trench 23 extending from capacitor diffusion layer 22b toward bit-line diffusion layer 22a.

Referring to the cross-sectional view of FIG. 14B, active region 1 is defined by first isolation region 3 formed on the front surface-side of p-type monocrystalline silicon semiconductor substrate (hereinafter described as “substrate”) 20. Two gate trenches 23 are formed in each active region 1. Gate insulating film 4 is formed on the inner surfaces of each gate trench 23. In addition, buried gate electrode 5 made of a laminated film composed of titanium nitride (TiN) and tungsten (W) and serving as a word line is formed so as to abut on gate insulating film 4 and bury the bottom of gate trench 23 (the boundary between titanium nitride and tungsten is not shown in FIG. 14B, and this is also true for other drawings). Cap insulating layer 6 abutting on the upper surface of buried gate electrode 5 and made of a silicon nitride film is formed on buried gate electrode 5.

Capacitor diffusion layer 22b to serve as part of a drain region is formed on a surface of substrate 20 between each gate trench 23 and each first isolation region 3. The bottom surface of capacitor diffusion layer 22b is positioned shallower than the upper surface of buried gate electrode 5 with respect to the upper surface of substrate 20, but may be so close as to be substantially flush with the upper surface of buried gate electrode 5. It is not preferable for the bottom surface of capacitor diffusion layer 22b to be positioned deeper than the upper surface of buried gate electrode 5, since the leakage current of gate insulating film 4 may increase.

Bit line 11 is formed above bit-line diffusion layer 22a. In addition, bit line 11 is connected to the upper surface of bit-line contact plug 11b buried in opening 11a of first interlayer insulating film 7a, and further to bit-line diffusion layer 22a through bit-line contact plug 11b and concave portion 1b connected to the lower surface of bit-line contact plug 11b. Bit line contact plug 11b is formed of an n-type impurity-containing polysilicon film, and bit line 11 is formed of a metal film. Bit line contact plug 11b is buried in opening 11a of first interlayer insulating film 7a, and bit line 11 extending in the X direction on the upper surface of first interlayer insulating film 7a is formed only of a metal film. A tungsten film, a metal nitride film, and a metal silicide film can be laminated as appropriate, to use the laminated film as the metal film. For example, the metal film can be composed of a titanium silicide film, a titanium nitride film, a tungsten silicide film, and a tungsten film in order from the lowermost layer. Cover insulating film 10 made of a silicon nitride film is formed on bit line 11.

Second interlayer insulating film 7 is formed on first interlayer insulating film 7a. Capacitive contact hole 24 is formed through second interlayer insulating film 7 and first interlayer insulating film 7a, so as to expose concave portion 1b on capacitor diffusion layer 22b. Sidewall insulating film 8 made of a silicon nitride film is provided on the inner sidewall surfaces of capacitive contact hole 24, and capacitor contact plug 9 made of a DOPOS (DOped PolySilicon) film is formed so as to fill capacitive contact hole 24. Contact pad 12 made of a conductive film, such as tungsten, is provided on second interlayer insulating film 7, so as to abut on capacitor contact plug 9. Silicon nitride film 13 is provided on second interlayer insulating film 7, and lower electrode 14 is formed so as to abut on contact pad 12. Support film 17 is provided so as to abut on the outer sidewall surfaces of the upper portion of lower electrode 14, in order to prevent the collapse of lower electrode 14. Capacitive insulating film 15 and upper electrode 16 are provided in order on the inner wall surfaces and outer sidewall surfaces of lower electrode 14. Lower electrode 14, capacitive insulating film 15 and upper electrode 16 constitute capacitor Cap. An unillustrated interlayer insulating film and an unillustrated contact plug are formed on upper electrode 16. Upper wiring (not illustrated) is formed in connection with the contact plug.

The semiconductor device of the present exemplary embodiment is such that width X₂ of concave portion (upper portion) 1b is larger than width X₁ of convex portion (lower portion) 1a. Accordingly, even if width X₁ of the convex portion (lower portion) becomes smaller as a DRAM is increasingly miniaturized, large alignment margins can be set at the time of forming a capacitor contact plug on active region 1. Thus, it is possible to reduce alignment failure in capacitor contact plugs. As the relationship among width X₂ of concave portion (upper portion) 1b, width X₁ of convex portion (lower portion) 1a, and thickness T₁ of silicon nitride film 3a, X₂=X₁+2×T₁. Since silicon nitride film 3a is formed using a film-forming method, such as a CVD method or an ALD method, the thickness of the silicon nitride film can be controlled with high accuracy. Consequently, concave portion 1b (upper surface of active region 1) can be set to a desired width by adjusting thickness T₁ of silicon nitride film 3a. As will be described later, concave portion (upper portion) 1b is formed in a self-aligned manner between silicon oxynitride films 3b across convex portion 1a in plan view. Thus, the DRAM, even if being miniaturized, is free from such constraints as the exposure accuracy of a lithography step. Accordingly, the semiconductor device can be made fully compatible with miniaturization. In addition, alignment failure in capacitor contact plug 9 can be reduced to improve the yield of the semiconductor device.

Note that although in the above-described configuration of the semiconductor device, concave portion 1b has been described as part of active region 1, the concave portion may be regarded as part of a contact plug. That is, a capacitor contact plug is composed of a first capacitor contact plug formed of concave portion 1b positioned on capacitor diffusion layer 22b of convex portion 1a, and a second capacitor contact plug formed of capacitor contact plug 9 buried in capacitive contact hole 24 penetrating through first interlayer insulating film 7a and second interlayer insulating film 7 and connected to the upper surface of first capacitor contact plug. Likewise, a bit-line contact plug is composed of a first bit-line contact plug formed of concave portion 1b positioned on bit-line diffusion layer 22a of convex portion 1a, and a second bit-line contact plug formed of bit-line contact plug 11b buried in opening 11a penetrating through first interlayer insulating film 7a and connected to the upper surface of the first bit-line contact plug.

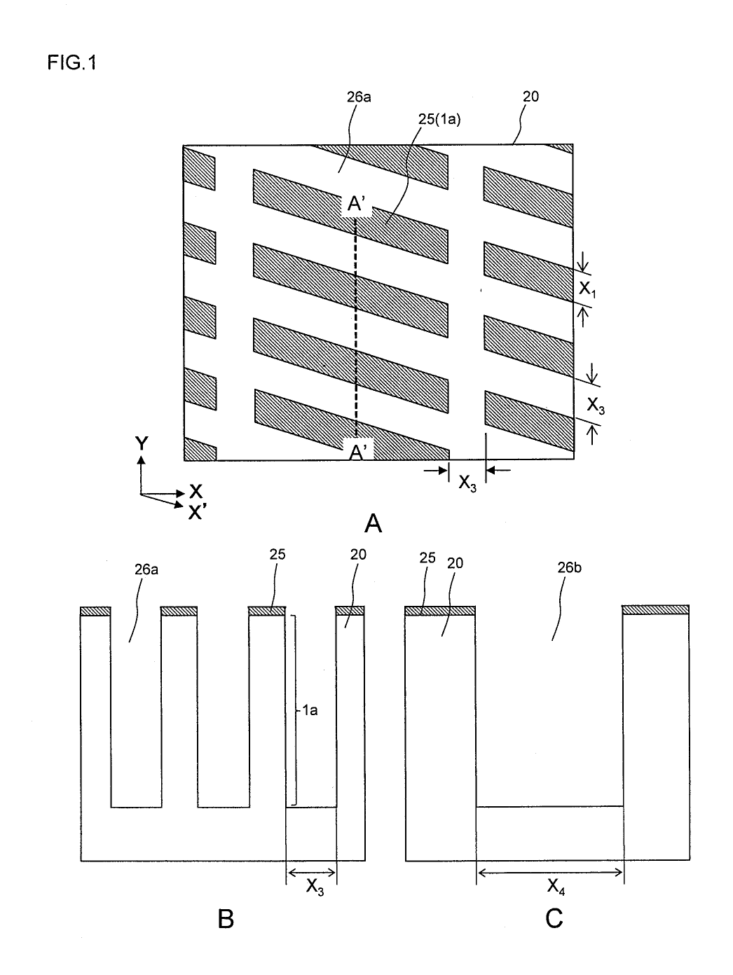

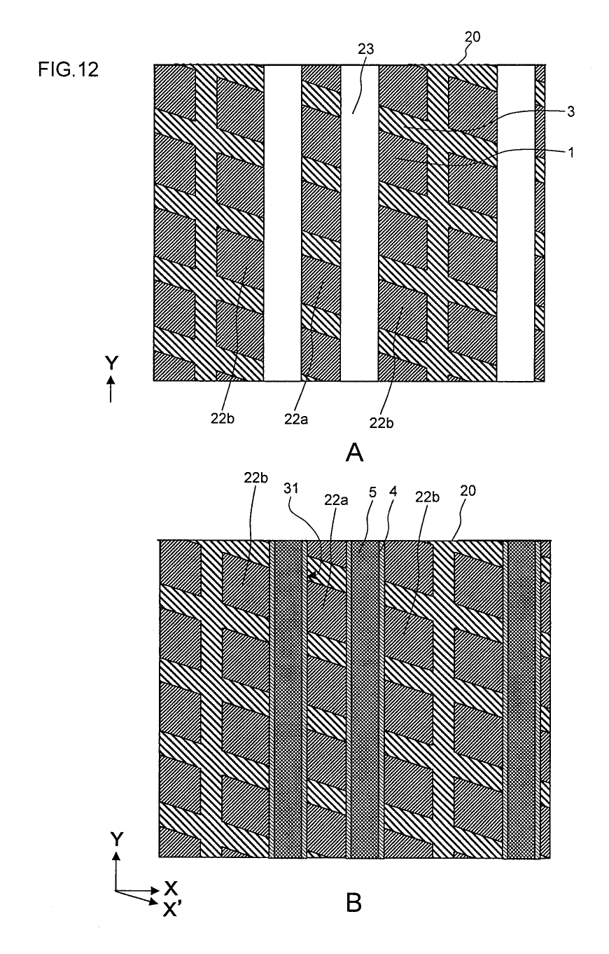

Hereinafter, a method for manufacturing a semiconductor device according to the present exemplary embodiment will be described using FIGS. 1 to 14. In FIGS. 1 to 11, each drawing A represents a plan view of part of a memory cell region, each drawing B represents a cross-sectional view taken along the A-A′ direction of drawing A, and each drawing C represents a cross-sectional view taken along the width direction of second isolation region 30 of a peripheral circuit region or a structure corresponding thereto. FIGS. 12A and 12B represent plan views of part of the memory cell region. FIG. 13A represents a plan view of part of the memory cell region, whereas FIG. 13B represents a cross-sectional view taken along the B-B′ direction of FIG. 13A.

As illustrated in FIG. 1, the principal surface of substrate 20 is thermally oxidized to form pad oxide film 25 having a thickness of 3 nm. Next, using heretofore-known lithography and dry etching techniques, trench 26a having width X₃ of 30 nm in both the X and Y directions is formed in a memory cell region of substrate 20 as a first trench, and trench 26b having width X₄ of, for example, 60 nm is formed in a peripheral circuit region as a second trench. Here, the depth of the first and second trenches is set to 250 nm. Consequently, island-shaped convex portion (lower portions) 1a of each active regions 1 divided off by trench 26a and having width X₁ of 30 nm in the Y direction is formed in the memory cell region. Convex portions 1a are regularly arranged at equal pitches in the Y and X′ directions.

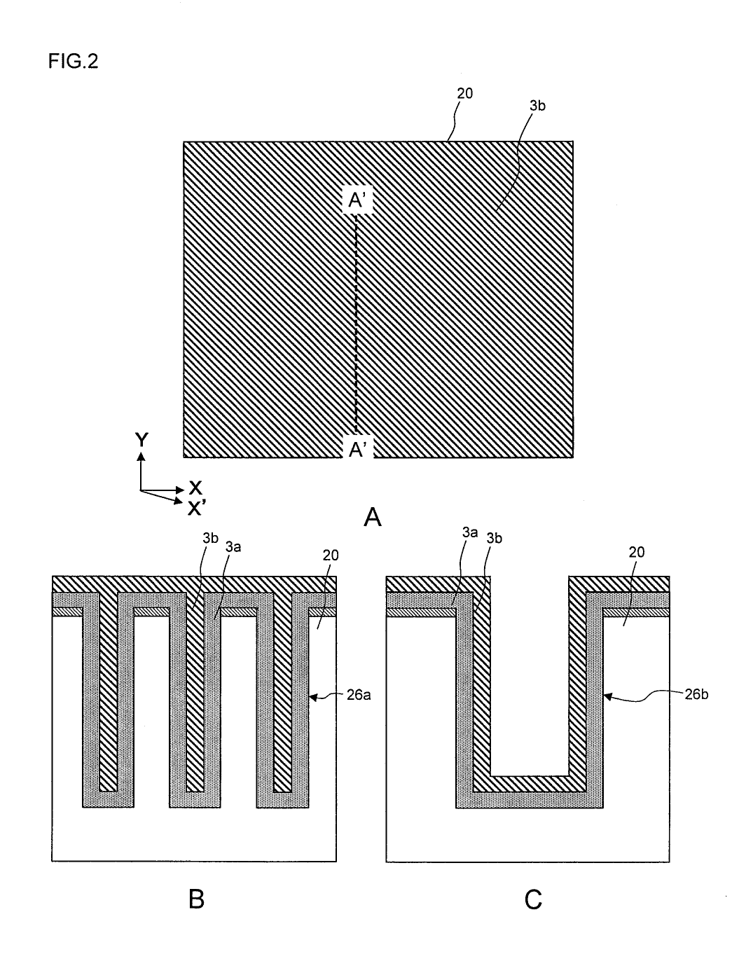

As illustrated in FIG. 2, silicon nitride film (Si₃N₄) (first insulating film) 3a having a thickness of 10 nm is formed on the entire surface of substrate 20 by a CVD method. This process forms silicon nitride film 3a having a thickness of 10 nm, so as to cover the inner surfaces of trench 26a having width X₃ of 30 nm in the Y direction. Consequently, a concave portion having a width of 10 nm in the Y direction is formed in the middle of trench 26a. Next, silicon oxynitride film (SiON) (second insulating film) 3b having a thickness of 10 nm is formed on the entire surface of substrate 20 by a CVD method. An SiON film is formed here in order to cause the ratio of O/N atoms composing the silicon oxynitride film to fall within the range of 0.7 to 1.5, preferably 0.9 to 1.1. The SiON film can be formed by controlling the amounts of ammonia and dinitrogen monoxide to be supplied in a CVD method using dichlorosilane (SiH₂Cl₂), ammonia (NH₃) and dinitrogen monoxide (N₂O) as raw material gases and the temperature range of 650 to 800° C., thereby obtaining silicon oxynitride film 3b having the abovementioned composition. Consequently, the concave portion formed in the middle of trench 26a and having a width of 10 nm in the Y direction is buried by silicon oxynitride film 3b. As a result, trench 26a formed to width X₃ of 30 nm in the Y direction is buried with silicon nitride film 3a and silicon oxynitride film 3b. On the other hand, trench 26b is formed so that width X₄ is 60 nm and is, therefore, not completely buried by silicon nitride film 3a and silicon oxynitride film 3b, thus leaving a cavity within the trench.

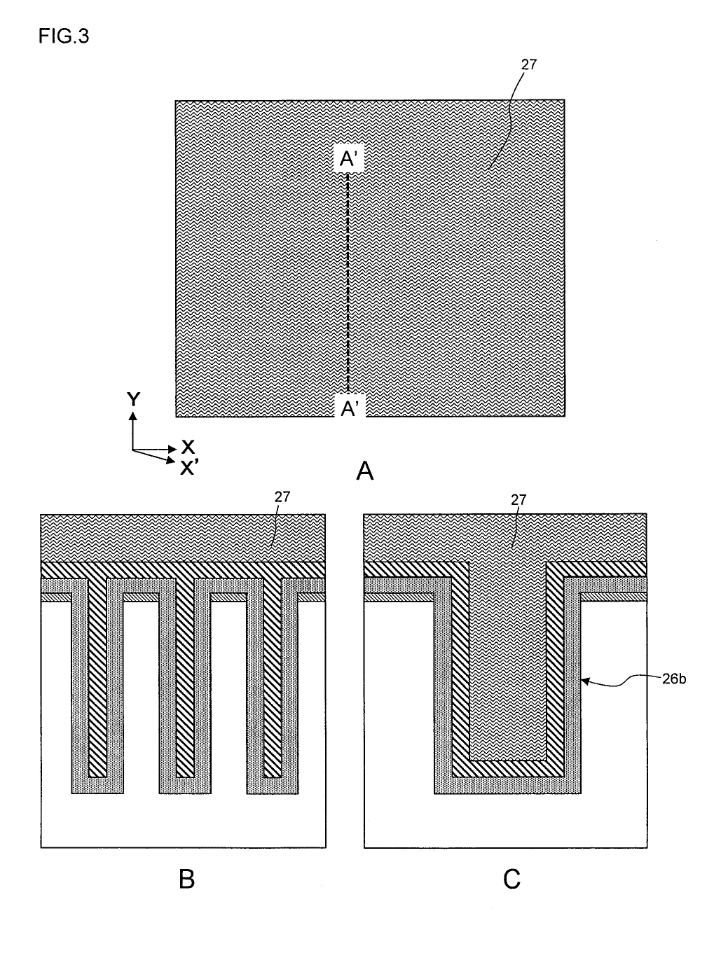

As illustrated in FIG. 3, silicon oxide film (third insulating film) 27 which is an SOD (Spin on Dielectric) film is formed on the entire surface of substrate 20 by a spin coating method, so as to bury the cavity remaining in trench 26b. Consequently, the inside of trench 26b is also filled with SOD film 27. After the formation of SOD film 27, the SOD film is heat-treated in an oxidizing atmosphere to densify the film.

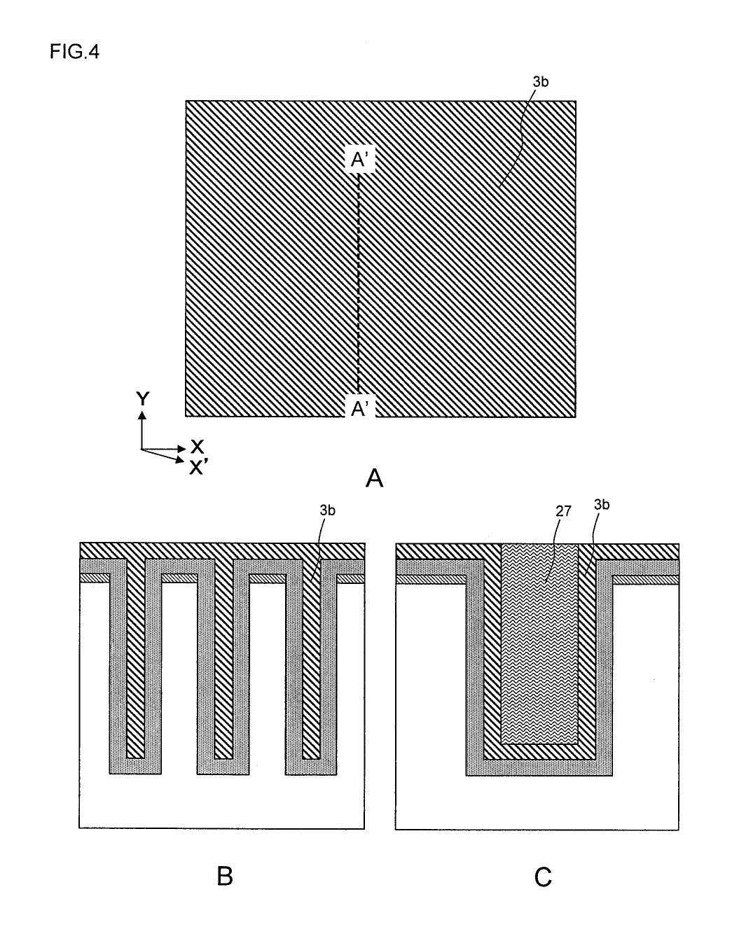

As illustrated in FIG. 4, SOD film 27 is CMP-treated using silicon oxynitride film 3b as a stopper to planarize a portion of SOD film 27 in the peripheral circuit region.

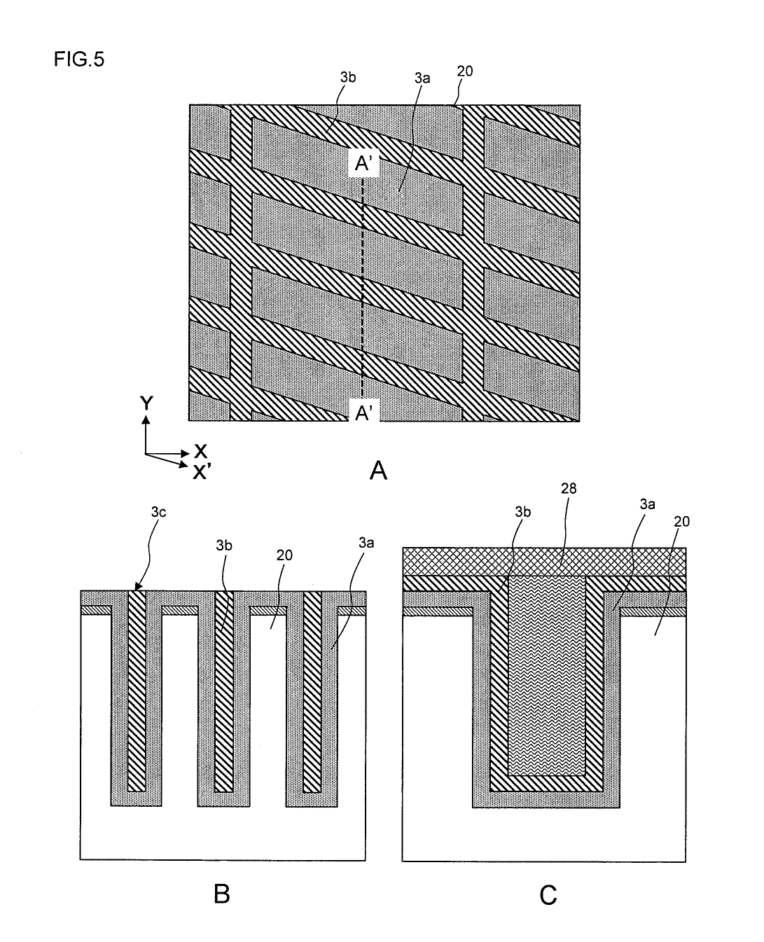

As illustrated in FIG. 5, polysilicon film 28 is formed on the entire surface of substrate 20 by a CVD method. Thereafter, a portion of polysilicon film 28 formed in the memory cell region is removed using heretofore-known lithography and dry etching techniques to leave over the polysilicon film only in the peripheral circuit region. Next, the upper surface of silicon oxynitride film 3b is set back downwardly by etch-back using a portion of polysilicon film 28 formed in the peripheral circuit region as a mask, until the upper surface of silicon nitride film 3a becomes exposed in the memory cell region. Consequently, the upper surface of silicon nitride film 3a and upper surface 3c of silicon oxynitride film 3b become flush with each other in the memory cell region.

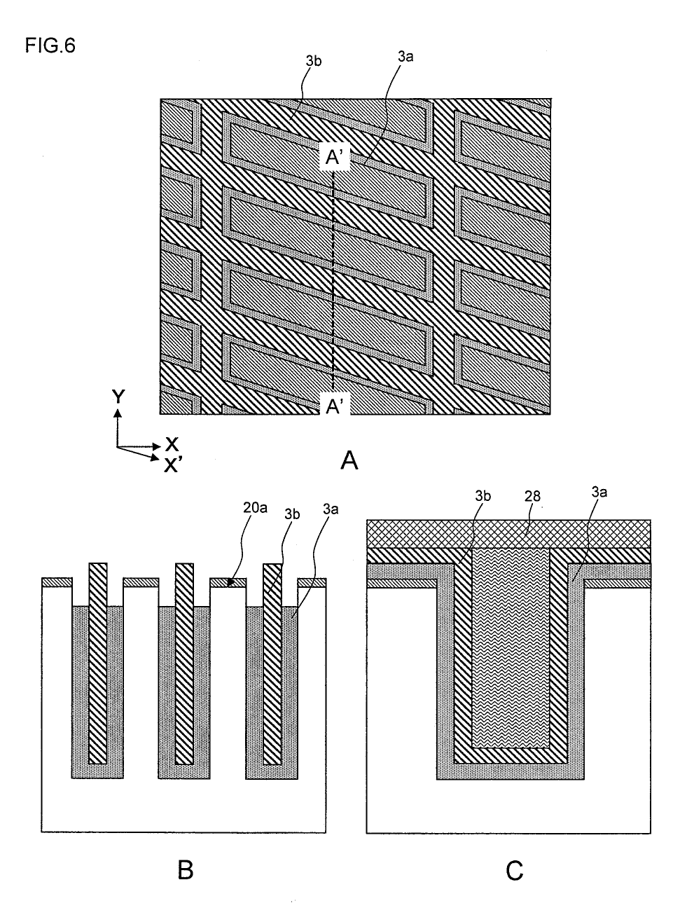

As illustrated in FIG. 6, part of silicon nitride film 3a exposed on the memory cell region is removed by wet etching using polysilicon film 28 as a mask and phosphoric acid as a chemical solution, to set back silicon nitride film 3a downwardly until the upper surface thereof is positioned lower than upper surface 20a of substrate 20. For example, the upper surface of silicon nitride film 3a is positioned 5 to 20 nm lower than upper surface 20a of substrate 20. Wet etching using phosphoric acid has the characteristic that a silicon nitride film is etched but a silicon oxide film is not etched. In the etching of silicon nitride film 3a by phosphoric acid, etching of silicon oxynitride film 3b also progresses. As described above, however, silicon oxynitride film 3b is formed so that the 0/N atomic ratio therein is in the range of 0.7 to 1.5. Thus, the etching rate of silicon oxynitride film 3b can be decreased to approximately 1/10 the etching rate of silicon nitride film 3a to leave over silicon oxynitride film 3b.

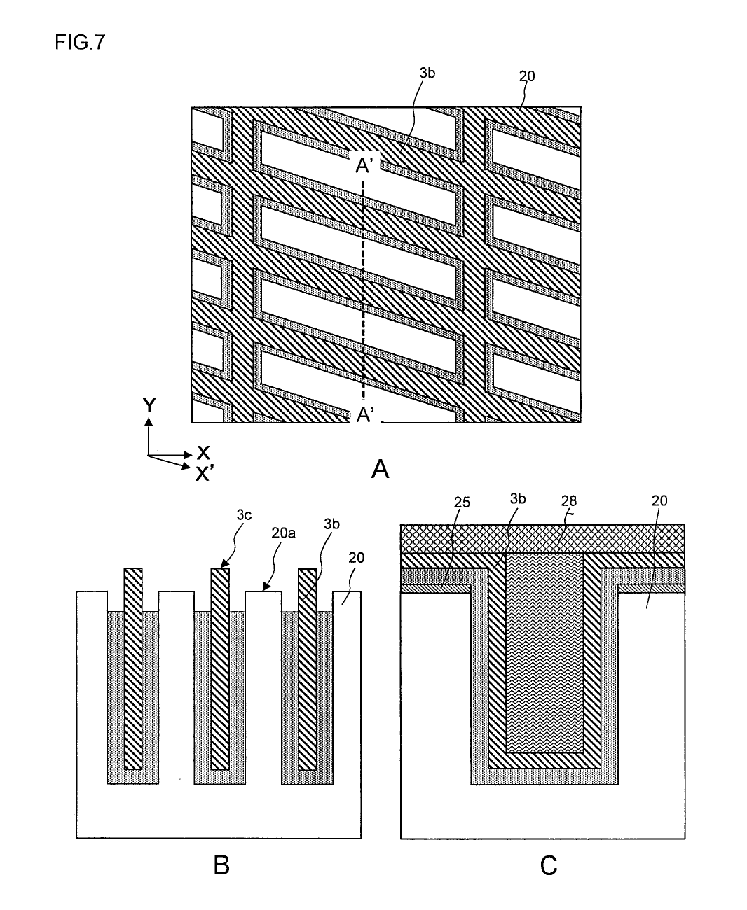

Next, as illustrated in FIG. 7, pad oxide film 25 in the memory cell region is removed by wet etching using polysilicon film 28 as a mask and hydrofluoric acid (HF) as a chemical solution. Contrary to wet etching using phosphoric acid, wet etching using an HF solution has the characteristic that a silicon oxide film is etched but a silicon nitride film is not etched. In the etching of pad oxide film 25 by an HF solution, etching of silicon oxynitride film 3b also progresses. As described above, however, silicon oxynitride film 3b is formed so that the O/N atomic ratio therein is in the range of 0.7 to 1.5. Thus, the etching rate of silicon oxynitride film 3b can be decreased to approximately 1/10 the etching rate of pad oxide film 25, to leave over silicon oxynitride film 3b. In addition, since pad oxide film 25 is 3 nm in thickness, and therefore, only a small amount thereof is removed if actually etched, thus causing no problems.

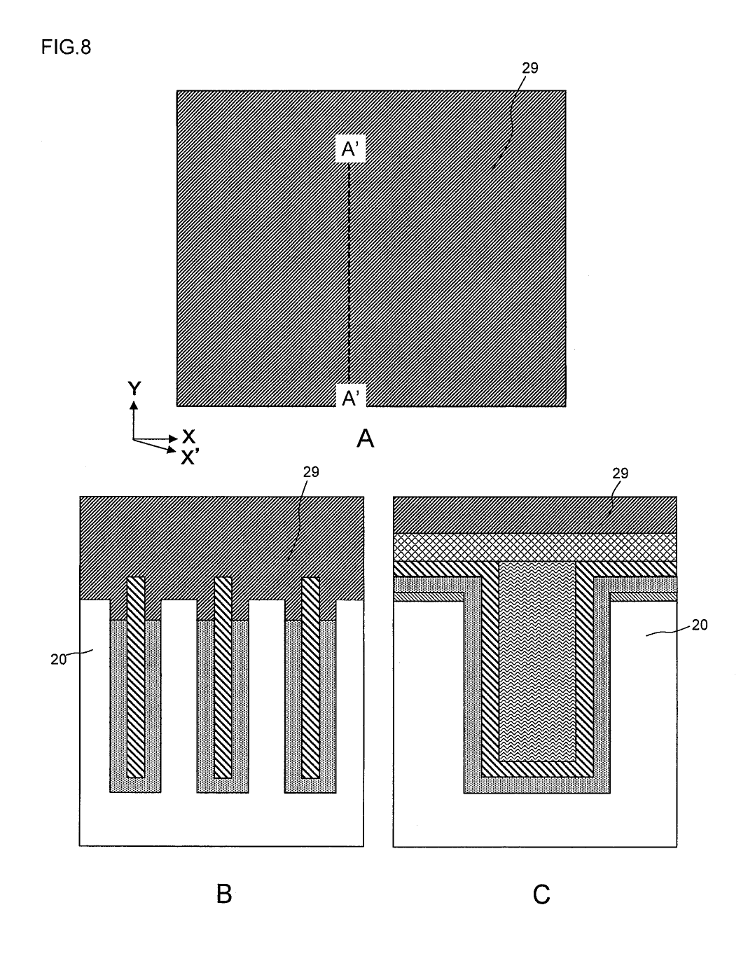

As illustrated in FIG. 8, amorphous silicon film 29 having a thickness of, for example, 40 nm and containing an N-type impurity is formed on the entire surface of substrate 20. Amorphous silicon film 29 is formed at a temperature of 530° C. using, for example, monosilane (SiH₄) and phosphine (PH₃) as raw material gases. This process forms phosphorus-containing amorphous silicon film 29.

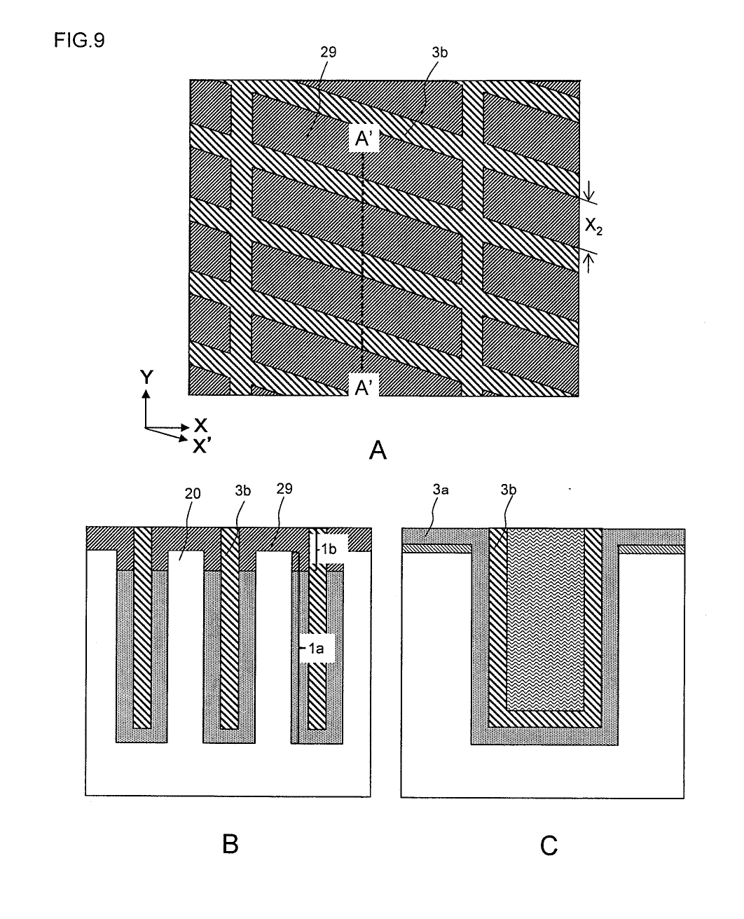

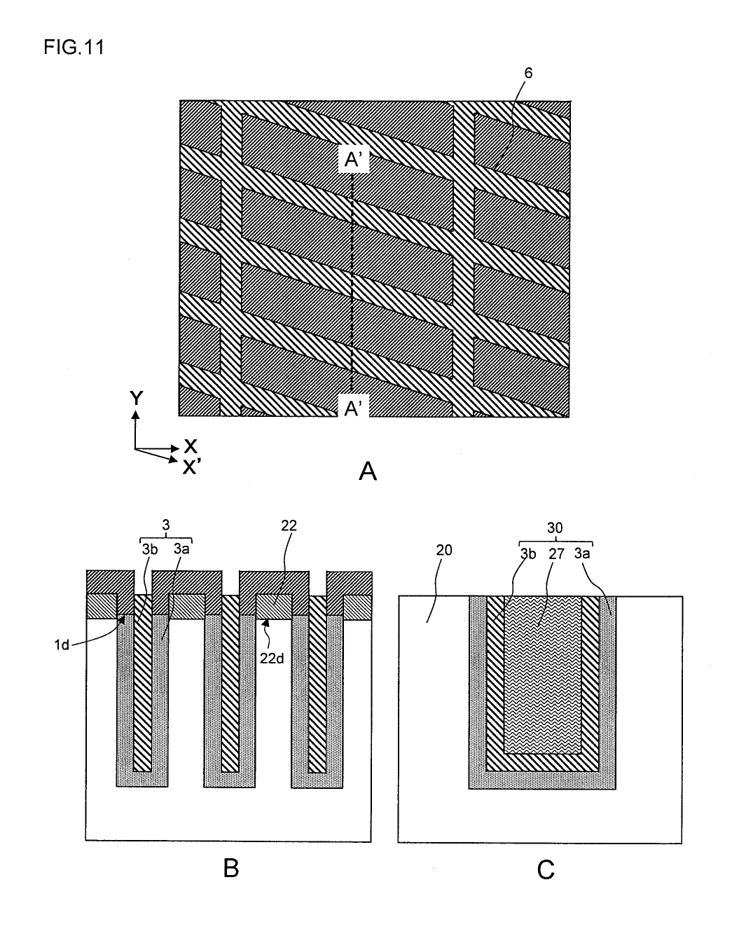

As illustrated in FIG. 9, part of amorphous silicon film 29 is removed by CMP treatment using silicon nitride film 3a as a stopper. At this time, silicon oxynitride film 3b formed on polysilicon film 28, amorphous silicon film 29 and silicon nitride film 3a provided in the peripheral circuit region is removed. In the memory cell region, this CMP treatment causes amorphous silicon film 29 to be partitioned by silicon oxynitride film 3b. Consequently, independent concave portions (upper portions) 1b are formed in correspondence with respective island-shaped active regions 1a. Each concave portion (upper portion) 1b is provided so as to continuously cover the upper surface and part of the side surfaces of each convex portion (lower portion) 1a. Each concave portion (upper portion) 1b has the shape of an upside-down concave structure, and is provided so that the leading end of each convex portion (lower portion) 1a abuts on the recess of the upside-down concave structure. Next, a heat treatment of, for example, 1000° C. and 10 seconds is performed in a non-oxidizing atmosphere. This heat treatment causes upward and lateral solid-phase epitaxial growth with underlying monocrystalline silicon substrate 20 serving as a seed, thereby converting amorphous silicon film 29 into a monocrystal epitaxially-grown silicon film containing an N-type impurity. Alternatively, amorphous silicon film 29 may be converted into a polysilicon film. In this case, heat treatment temperature may be set to 700° C. Note that this heat treatment need not be performed at this stage, but may be performed together with a step to be carried out after an impurity element is ion-implanted into active regions 1 in FIG. 11.

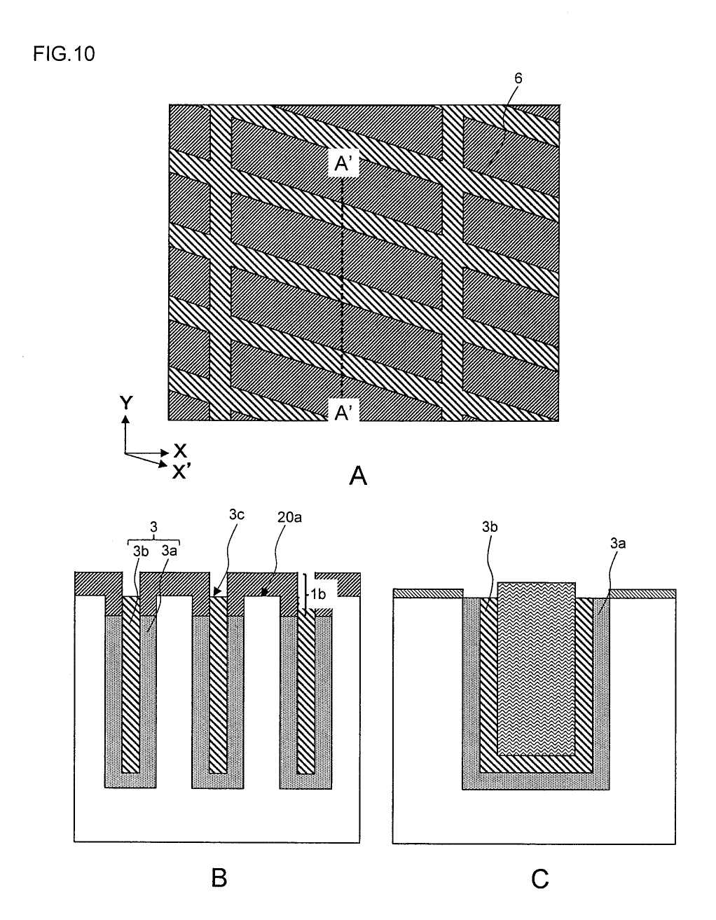

As illustrated in FIG. 10, silicon nitride film 3a and silicon oxynitride film 3b are etched back by a dry etching method to set back the upper surfaces of these films. Silicon nitride film 3a and silicon oxynitride film 3b can be etched at the same rate by a dry etching method using fluorine-containing plasma. At this point in time, the structure of concave portion (upper portion) 1b is complete. Accordingly, upper surface 3c of silicon oxynitride film 3b may be substantially level with or positioned lower than upper surface 20a of substrate 20 in the memory cell region. This process brings first isolation region 3 composed of silicon nitride film 3a and silicon oxynitride film 3b to completion in the memory cell region.

As illustrated in FIG. 11, a photoresist mask (not illustrated) is provided in the memory cell region. Thereafter, pad oxide film 25, silicon nitride film 3a, silicon oxynitride film 3b and SOD film 27 are etched back, so that the upper surfaces of substrate 20, silicon nitride film 3a, silicon oxynitride film 3b and SOD film 27 are flush with one another. This process forms second isolation region 30 composed of these films in the peripheral circuit region. Next, the photoresist mask is removed, and then a photoresist (not illustrated) is provided in the peripheral circuit region. An impurity element is ion-implanted into active regions 1 and activated by performing a 1000° C., 10-second heat treatment. This process forms diffusion layer 22 in each active region 1. Note that in the formation of diffusion layer 22, the depth of ion implantation is controlled, so that bottom surface 22d of diffusion layer 22 is deeper than lower surface 1d of the concave portion and shallower than the upper surface of gate electrode 5 to be described later. The formation of diffusion layer 22 may be performed at the stage of FIG. 9. That is, ion implantation may be performed before amorphous silicon film 29 is subjected to solid-phase epitaxial growth at the stage of FIG. 9. Thereafter, a 1000° C., 10-second heat treatment may be performed to simultaneously perform both the solid-phase epitaxial growth of amorphous silicon film 29 and the activation of the implanted impurity, thereby forming diffusion layer 22.

Next, as illustrated in FIG. 12A, a photoresist mask (not illustrated) having a pattern to expose thereon a word line region to be formed in the memory cell region is formed using a lithography technique. Thus, the word line region is patterned so as to extend in the Y direction across pluralities of active regions 1 and first isolation regions 3. Two word line regions are formed for each active region 1. The width of each word line region in the X direction is set to 35 nm. Subsequently, substrate 20 is dry-etched using the photoresist mask to form 150 to 200 nm-deep gate trenches 23 to serve as word line regions. Here, the depth of the deepest portion of each gate trench 23 is set to 200 nm. This process causes each diffusion layer 22 formed at the stage of FIG. 11 to be segmented into capacitor diffusion layer 22b to be connected to a capacitor and bit-line diffusion layer 22a to be connected to a bit line.

Next, as illustrated in FIG. 12B, gate insulating film 4 made of a silicon oxide film having a thickness of 5 nm is formed on the inner surfaces of each gate trench 23 by a thermal oxidation method. Subsequently, a titanium nitride (TiN) having a thickness of 5 nm is formed by a CVD method, and a tungsten (W) having a thickness of 30 nm is additionally formed by a CVD method. Since the width of gate trench 23 in the X direction is set to 35 nm, gate trench 23 is placed in a state of being completely buried by a laminated film of TiN and W at this stage. Subsequently, the laminated film composed of TiN and W is etched back by a dry etching method to form buried gate electrode 5 buried in each gate trench 23 and composed of TiN and W. Each buried gate electrode 5 which buries the bottom of gate trench 23 is formed so that the position of the upper surface of buried gate electrode 5 is within the range of ½ to ⅘ the depth of the deepest portion of gate trench 23. Here, the upper surface is set to 120 nm in depth which is ⅗ the abovementioned depth. Since the depth of the deepest portion of each gate trench 23 is set to 200 nm, the upper surface of each buried gate electrode 5 is formed in a position 80 nm deeper than the upper surface of substrate 20. Buried gate electrodes 5 constitute word lines. As the result of buried gate electrodes 5 being formed, new gate trenches 23 are formed on the buried gate electrodes 5.

Next, as illustrated in FIG. 13, cap insulating layer 6 made of a silicon nitride film is formed on the entire surface of substrate 20 by a CVD method, so as to bury new gate trenches 23. Thereafter, cap insulating layer 6 is etched back to set back the upper surface thereof so as to be level with the upper surface of concave portion 1b. Next, first interlayer insulating film 7a is formed on the entire surface of substrate 20. Thereafter, linear opening 11a to collectively open up therein a plurality of concave portions 1b formed on bit-line diffusion layers 22a adjacent to one another on a straight line in the Y direction is formed in first interlayer insulating film 7a by lithography and dry etching methods.

Next, an n-type impurity-containing amorphous silicon film having a thickness of 40 nm is formed on the entire surface of substrate 20 by a CVD method. Next, the amorphous silicon film containing the n-type impurity is planarized by a CMP method and buried in opening 11a. Next, a heat treatment of approximately 700° C. and 10 seconds is performed to convert the n-type impurity-containing amorphous silicon film buried in opening 11a into an n-type impurity-containing polysilicon film. Next, a metal layer composed of titanium silicide, titanium nitride, tungsten silicide, tungsten laminated in order therein is formed on the entire surface of substrate 20, including the upper surface of the n-type impurity-containing polysilicon film buried in opening 11a and the upper surface of first interlayer insulating film 7a.

Thereafter, cover insulating film 10 made of a silicon nitride film is formed on the metal layer. Next, there is formed a mask (not illustrated) having a pattern extending in the X direction to linearly create openings. Using the mask, cover insulating film 10 the upper surface of which is exposed is dry-etched and, in succession, the metal layer and the n-type impurity-containing polysilicon film buried in opening 11a are dry-etched. Consequently, on bit-line diffusion layer 22a, there are formed bit-line contact plug 11b composed of the n-type impurity-containing polysilicon film buried in opening 11a through concave portion 1b, bit line 11 connected to the upper surface of bit-line contact plug 11b and made of the metal layer extending in the X direction on first interlayer insulating film 7a, and a wiring structure composed of cover insulating film 10 covering the upper surface of the bit line. Bit-line contact plug 11b and bit line 11 are continuously etched using cover insulating film 10 as a mask. Accordingly, two side surfaces of bit-line contact plug 11b opposed to each other in the Y direction and two side surfaces opposed to each other in the Y direction of the bit line 11 positioned on the upper surface of bit-line contact plug 11b are flush with each other, respectively.

Next, second interlayer insulating film 7 made of an SOD (Spin On Dielectric) film is formed on the entire surfaces of first interlayer insulating film 7a and the bit-line wiring structure as a coating-based insulating film. Using cover insulating film 10 as a stopper, second interlayer insulating film 7 is CMP-treated to planarize the second interlayer insulating film 7. Using heretofore-known lithography and dry etching techniques, capacitive contact hole 24 is formed in first interlayer insulating film 7a and second interlayer insulating film 7, so as to expose concave portion 1b on capacitor diffusion layer 22b. A silicon nitride film is formed on the entire surface of substrate 20, and then etched back to form sidewall insulating film 8 on the inner sidewall surfaces of capacitive contact hole 24. A DOPOS (DOped Polysilicon) film is formed on the entire surface of substrate 20, so as to fill capacitive contact hole 24, and then etched back to form capacitor contact plug 9.

As illustrated in FIG. 14, a conductive film, such as tungsten, is formed on second interlayer insulating film 7, and then patterned to form contact pad 12. Using an ALD method, third interlayer insulating film 13 made of a silicon nitride film is formed on second interlayer insulating film 7, so as to cover contact pads 12. Using a CVD method, fourth interlayer insulating film (not illustrated) made of a silicon oxide film and support film 17 made of a silicon nitride film are formed on third interlayer insulating film 13. Using heretofore-known lithography and dry etching techniques, capacitor holes 32 are formed in the fourth interlayer insulating film and support film 17, so as to expose contact pads 12. Using a CVD method, a conductive film made of titanium nitride is formed so as to cover the inner walls of each capacitor hole 32. A portion of the conductive film on support film 17 is removed by etch-back to leave over the conductive film only on the inner walls of each capacitor hole 32, thereby forming lower electrode 14.

Using heretofore-known lithography and dry etching techniques, openings for wet etching to be described later are provided in support film 17. Using support film 17 provided with the openings as a mask, the fourth interlayer insulating film is removed by wet etching using an HF solution as an etching liquid. This process exposes the outer sidewall surfaces of lower electrode 14. Using an ALD method, capacitive insulating film 15 is formed on the entire surface of substrate 20. As capacitive insulating film 15, it is possible to use a high-dielectric constant film, such as zirconium oxide (ZrO₂), aluminum oxide (Al₂O₃) or hafnium oxide (HfO₂), or a laminated film of these oxides. Next, upper electrode 16 made of a titanium nitride film is formed by a CVD method. Upper electrode 16 may be formed into a laminated structure in which after the formation of a titanium nitride film, an impurity-doped polysilicon film is laminated to fill the cavity between adjacent lower electrodes 14, and tungsten (W) is film-formed on the polysilicon film. This process brings capacitor Cap composed of lower electrode 14, capacitive insulating film 15 and upper electrode 16 to completion.

Next, a mask pattern using a photoresist film (not illustrated) is formed in order to pattern upper electrode 16. Unnecessary films (upper electrode 16, capacitive insulating film 15, and support film 17) on the peripheral circuit region are removed by dry etching using the mask pattern. After etching, the photoresist film is removed. A fifth interlayer insulating film (not illustrated) is formed on the entire surface of substrate 20, and then planarized by CMP. Contact plugs and wiring layers (none of which are illustrated) are formed in the memory cell region and the peripheral circuit region.

In the present exemplary embodiment, each concave portion (upper portion) 1b is formed in the steps of FIGS. 8 and 9, so as to cover the upper and side surfaces of each convex portion (lower portion) 1a in the active region. Accordingly, the width of the upper surface of active region 1 has expanded from initial width X₁ of convex portion (lower portion) 1a to width X₂ of the upper surface of concave portion (upper portion) 1b. Consequently, large alignment margins can be set at the time of forming capacitive contact holes 24 in the step of FIG. 13. As a result, the occurrence of defective units resulting from the alignment failure of capacitive contact holes 24 can be suppressed to improve the yield of semiconductor devices. That is, electrical discontinuity can be avoided and contact resistance can be reduced by expanding the contact area between each capacitor contact plug 9 and each active region 1. In addition, concave portion (upper portion) 1b is formed after the completion of first isolation region 3 and can therefore be fully compatible with miniaturization.

Yet additionally, the present invention allows large alignment margins to be set at the time of forming not only capacitive contact holes 24 but also bit line contact holes. As a result, the occurrence of defective units resulting from the alignment failure of contact holes can be suppressed to improve the yield of semiconductor devices.

### Second Exemplary Embodiment

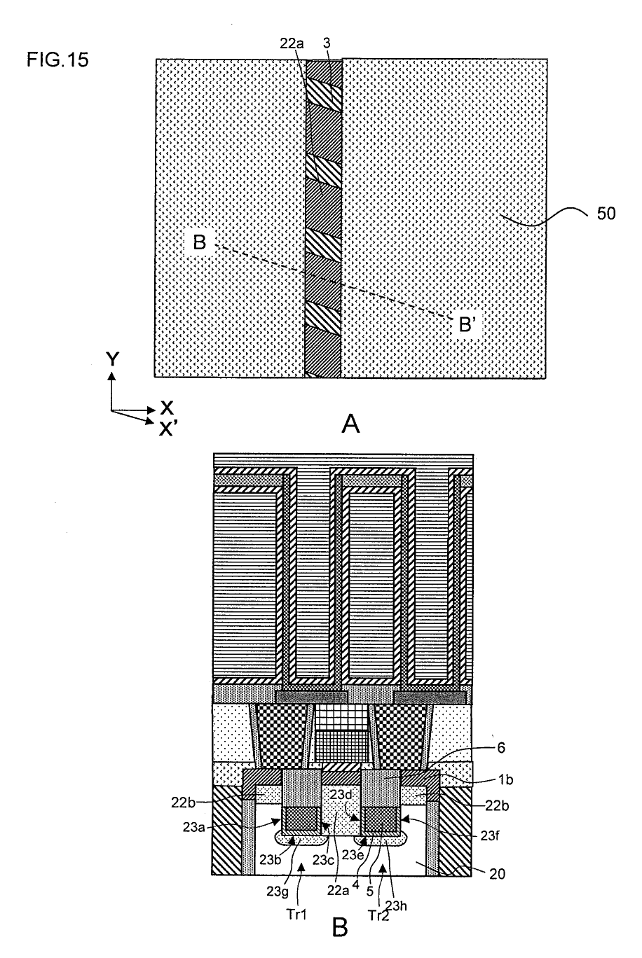

In the First Exemplary Embodiment, a description has been given of a DRAM semiconductor device having a configuration in which the channel portions of each of buried-gate transistors Tr1 and Tr2 are respectively formed on three surfaces, i.e., two side surfaces and the bottom surface of each gate trench 23, in each active region 1 the upper surface area of which is expanded as the result of concave portion 1b being formed on convex portion 1a. In the present exemplary embodiment, a description will be given of an example, using FIG. 15, in which a buried-gate transistor formed in each active region 1 having the same structure as described above differs in configuration from gate transistors.

FIG. 15B illustrates a cross-sectional view in the present exemplary embodiment corresponding to FIG. 14B in First Exemplary Embodiment. Constituent elements other than the buried-gate transistors are the same as those of FIG. 14B, and therefore, will not be described again here.

In FIG. 12 in First Exemplary Embodiment, gate trench 23 extending in the Y direction is formed, and then an n-type impurity, such as phosphorous or arsenic, is ion-implanted into a surface of semiconductor substrate 20 exposed on the bottom of gate trench 23. Thereafter, a heat treatment of 1000° C. and 10 seconds is performed to form bottom diffusion layers 23g and 23h abutting on bottom surfaces 23b and 23e of gate trenches 23. Conditions of ion implantation are controlled so that the depth of bottom diffusion layer 23g falls within the range of 5 to 20 nm from bottom surface 23b. The same holds true for the depth of bottom diffusion layer 23h. Next, the steps of forming gate insulating film 4, buried gate electrode 5 and cap insulating layer 6 are carried out as in First Exemplary Embodiment.

Thereafter, mask pattern 50 for linearly and collectively opening up concave portions 1b on bit-line diffusion layers 22a adjacent to one another in the Y direction is formed as illustrated in FIG. 15A. Next, phosphorous is ion-implanted using mask pattern 50 as a mask. At this time, ion implantation is controlled so that the depth of implantation agrees with bottom surfaces 23b and 23e of gate trenches 23. If the depth of the gate trenches is set to 200 nm as in the case of First Exemplary Embodiment, the bottom diffusion layers are formed by implanting phosphorous twice under energy conditions having projected ranges in depth of 50 nm and 150 nm. Alternatively, the bottom diffusion layers may be formed by implanting phosphorous three times under energy conditions having projected ranges in depth of 50 nm, 110 nm and 170 nm. After mask pattern 50 is removed, a heat treatment of 1000° C. and 10 seconds is performed to form bit-line diffusion layers 22a. This process causes bit-line diffusion layers 22a to be connected to bottom diffusion layers 23g and 23e.

As illustrated in FIG. 15B, two buried gate-type MOS transistors Tr1 and Tr2 are formed in each active region 1. MOS transistor Tr1 is composed of gate insulating film 4 formed on the inner surfaces of gate trench 23, buried gate electrode 5 buried in gate trench 23 and formed on gate insulating film 4, a drain region formed of concave portion 1b and capacitor diffusion layer 22b, and a source region formed of concave portion 1b, bit-line diffusion layer 22a and bottom diffusion layer 23g. Since bottom diffusion layer 23g is connected to bit-line diffusion layer 22a, MOS transistor Tr1 is equivalent in configuration to a MOS transistor in which bit-line diffusion layer 22a extends to the bottom surface of gate trench 23. Accordingly, though MOS transistor Tr1 of the present exemplary embodiment includes side surfaces 23a and 23c and bottom surface 23b constituting gate trench 23, bottom surface 23b abutting on bottom diffusion layer 23g and side surface 23c abutting on bit-line diffusion layer 22a do not function as channels. That is, only side surface 23a opposed to isolation region 3 and not in contact with the diffusion layer functions as a channel.

MOS transistor Tr2 is the same in configuration as MOS transistor Tr1 and composed of gate insulating film 4 formed on the inner surfaces of gate trench 23, buried gate electrode 5 buried in gate trench 23 and formed on gate insulating film 4, a drain region formed of concave portion 1b and capacitor diffusion layer 22b, and a source region formed of concave portion 1b, bit-line diffusion layer 22a and bottom diffusion layer 23h. Since bottom diffusion layer 23h is connected to bit-line diffusion layer 22a, MOS transistor Tr2 is equivalent in configuration to a MOS transistor in which bit-line diffusion layer 22a extends to the bottom surface of gate trench 23. Accordingly, though MOS transistor Tr2 includes side surfaces 23d and 23f and bottom surface 23e constituting gate trench 23, bottom surface 23e abutting on bottom diffusion layer 23h and side surface 23d abutting on bit-line diffusion layer 22a do not function as channels. That is, only side surface 23f opposed to isolation region 3 and not in contact with the diffusion layer functions as a channel. In this case, bit-line diffusion layer 22a serves to connect bottom diffusion layers 23g and 23h positioned in the bottoms of two adjacent gate trenches 23.

According to the semiconductor device of the present exemplary embodiment, electrical discontinuity can be avoided and contact resistance can be reduced by expanding the contact area between each capacitor contact plug and each active region, as in First Exemplary Embodiment. In addition, the channel region of a buried gate-type MOS transistor is formed only on one side surface of each gate trench 23 to reduce a channel length. Consequently, channel resistance can be reduced to increase the on-state current of the transistor, and a subthreshold coefficient (S coefficient) can be reduced to provide a transistor advantageous in high-speed operation.

Note that in First and Second Exemplary Embodiments described above, the description has been given assuming a memory cell including island-shaped active regions segmented in the X and Y directions. The exemplary embodiments are not limited to these active regions, however. Linear active regions which are isolated only in the Y direction by an isolating insulating film can provide the same advantageous effects because the active regions in the Y direction can be expanded. In this case, a memory cell configuration can be adopted in which field shielding using dummy gate electrodes is applied for isolation in the X direction.

It is apparent that the present invention is not limited to the above embodiments, but may be modified and changed without departing from the scope and spirit of the invention.

The following methods for manufacturing a semiconductor device also fall within the scope of the present invention:

1. A method for manufacturing a semiconductor device, comprising:

forming a first trench in a semiconductor substrate to form a convex portion divided off by the first trench; and

forming a concave portion, so as to cover an upper surface and a side surface of the convex portion.

2. The method for manufacturing a semiconductor device according to item 1,

wherein the forming the concave portion comprises:

forming a first insulating film on an inner wall of the first trench in a memory cell region;

forming a second insulating film on the first insulating film, so that the second insulating film fills the first trench and an upper surface of the second insulating film is higher than an upper surface of the semiconductor substrate; and

forming a conductive film on the convex portion, so that an upper surface of the conductive film is lower than the upper surface of the second insulating film, to form the concave portion.

3. The method for manufacturing a semiconductor device according to item 2,

wherein in the forming the convex portion, a second trench is further formed in a peripheral circuit region,

in the forming the first insulating film, the first insulating film Is further formed on an inner wall of the second trench, and

in the forming the second insulating film, the second insulating film is further formed on the first insulating film within the second trench, and

wherein the method further comprises forming a third insulating film on the second insulating film, so as to fill the second trench, after the forming the second insulating film.

4. The method for manufacturing a semiconductor device according to item 2,

wherein the first insulating film is a silicon nitride film.

5. The method for manufacturing a semiconductor device according to item 2,

wherein the second insulating film is a silicon oxynitride film.

6. The method for manufacturing a semiconductor device according to item 1, further comprising, after the forming the concave portion:

forming a gate electrode, so as to be opposed to the convex portion with a gate insulating film interposed between the gate electrode and the convex portion;

forming a pair of diffusion layers, so as to sandwich the gate electrode within the convex portion and the concave portion; and

forming a contact plug on the concave portion, so as to be electrically connected to at least one of the diffusion layers.

7. The method for manufacturing a semiconductor device according to item 6,

wherein in the forming the gate electrode, a buried gate electrode is formed so as to be buried in the convex portion, and

in the forming the contact plug, the contact plug is formed so as to be electrically connected to one of the diffusion layers, and

wherein the method further comprises:

forming a capacitor so as to be electrically connected to the contact plug; and

forming a bit line, so as to be electrically connected to the other one of the diffusion layers.

What is claimed is:

1. A semiconductor device comprising:
a convex portion;
a concave portion provided so as to cover an upper surface and a part of a side surface of the convex portion;
a gate electrode provided within the convex portion, so as to be opposed to the convex portion with a gate insulating film interposed between the gate electrode and the convex portion;
a pair of diffusion layers provided so as to sandwich the gate electrode within the convex portion and the concave portion; and
a contact plug provided on the concave portion, so as to be electrically connected to at least one of the diffusion layers.

2. The semiconductor device according to claim 1, further comprising:
a first isolation region in a memory cell region, the first isolation region including a first insulating film provided on an inner wall surface of a first trench provided around the convex portion and the concave portion so as to define the convex portion and the concave portion, and a second insulating film provided on the first insulating film so as to fill the first trench,
wherein an upper surface of the first insulating film abuts on a lower surface of the concave portion.

3. The semiconductor device according to claim 2, further comprising:
a second isolation region in a peripheral circuit region, the second isolation region including the first insulating film provided on an inner wall surface of a second trench, and the second insulating film and a third insulating film provided in order on the first insulating film so as to fill the second trench.

4. The semiconductor device according to claim 2,
wherein the first insulating film is a silicon nitride film.

5. The semiconductor device according to claim 2,
wherein the second insulating film is a silicon oxynitride film.

6. The semiconductor device according to claim 3,
wherein the third insulating film is a silicon oxide film.

7. The semiconductor device according to claim 1,
wherein the gate electrode is a buried gate electrode buried in the convex portion, and
the contact plug is provided so as to be electrically connected to one of the diffusion layers, and
wherein the semiconductor device further comprises:
a capacitor electrically connected to the contact plug that is electrically connected to the one of the diffusion layers; and
a bit line provided so as to be electrically connected to the other one of the diffusion layers.

8. The semiconductor device according to claim 1,
wherein the convex portion is an active region, and
the gate insulating film, the gate electrode and the pair of diffusion layers constitute a transistor.

9. The semiconductor device according to claim 1,
wherein the concave portion includes impurity-containing silicon.

10. A semiconductor device comprising:
a first region including an upper portion, a lower portion having a smaller width than the upper portion, and a level difference formed by a discontinuous variation of widths of the upper portion and the lower portion;
a gate electrode provided within the first region, so as to be opposed to the first region with a gate insulating film interposed between the gate electrode and the first region;
a pair of diffusion layers provided within the first region so as to sandwich the gate electrode; and
a contact plug provided on the upper portion, so as to abut on at least one of the diffusion layers.

11. The semiconductor device according to claim 10,
wherein the lower portion is formed of an active region, and
the gate insulating film, the gate electrode and the pair of diffusion layers constitute a transistor.

12. A semiconductor device comprising:
a first region including a first upper portion and a first lower portion having a smaller width than the first upper portion;
a second region including a second upper portion and a second lower portion having a smaller width than the second upper portion;
a first isolation region provided between the first and second regions, so as to cover side surfaces of the first and second regions;
a first gate electrode provided within the first region, so as to be opposed to the first region with a first gate insulating film interposed between the first gate electrode and the first region;
a second gate electrode provided within the second region, so as to be opposed to the second region with a second gate insulating film interposed between the second gate electrode and the second region;
a pair of first diffusion layers provided within the first region so as to sandwich the first gate electrode;
a pair of second diffusion layers provided within the second region so as to sandwich the second gate electrode;
a first contact plug provided on the first region, so as to be electrically connected to at least one of the first diffusion layers; and
a second contact plug provided on the second region, so as to be electrically connected to at least one of the second diffusion layers.

13. The semiconductor device according to claim 12,
wherein the first isolation region comprises:
a first insulating film provided so as to abut on a lower surface of the first upper portion and a side surface of the first lower portion and so as to abut on a lower surface of the second upper portion and a side surface of the second lower portion; and
a second insulating film provided on the first insulating film, so as to abut on side surfaces of the first and second upper portions.

14. The semiconductor device according to claim 13,
wherein the first insulating film is a silicon nitride film.

15. The semiconductor device according to claim 13,
wherein the second insulating film is a silicon oxynitride film.

16. The semiconductor device according to claim 12,
wherein the first and second gate electrodes are buried gate electrodes buried in the first and second regions, respectively,
the first contact plug is provided so as to be electrically connected to one of the first diffusion layers, and
the second contact plug is provided so as to be electrically connected to one of the second diffusion layers, and
wherein the semiconductor device further comprises:
a first capacitor electrically connected to the first contact plug;
a second capacitor electrically connected to the second contact plug;
a first bit line provided so as to be electrically connected to the other one of the first diffusion layers; and
a second bit line provided so as to be electrically connected to the other one of the second diffusion layers.

17. The semiconductor device according to claim 12,
wherein the first and second upper portions include impurity-containing silicon.
